(19) United States
(12) Patent Application Publication
(10) Pub. No.: US 2026/0081602 A1
(43) Pub. Date: Mar. 19, 2026

(54) POWER SUPPLY CIRCUIT, SIGNAL TRANSMISSION DEVICE, ELECTRONIC DEVICE, AND VEHICLE

(71) Applicant: ROHM CO., LTD., Kyoto-shi (JP)

(72) Inventor: Masahiko ARIMURA, Kyoto-shi (JP)

(21) Appl. No.: 19/399,941

(22) Filed: Nov. 25, 2025

Related U.S. Application Data
(63) Continuation of application No. PCT/JP2024/014715, filed on Apr. 11, 2024.

(30) Foreign Application Priority Data
Jun. 2, 2023 (JP) 2023-091614

(51) Int. Cl. H03K 17/691; H03K 3/037

(52) U.S. Cl. CPC H03K 17/691; H03K 3/037

(57) ABSTRACT

A power supply circuit generates from the input voltage of a primary circuit system the output voltage of a secondary circuit system by driving a switching output stage. The power supply circuit includes: a pulse feedback signal generation circuit that generates a pulse feedback signal corresponding to the output voltage; an analog control signal generation circuit that generates an analog control signal corresponding to the pulse feedback signal; and a switching driving control circuit that drives the switching output stage according to the result of comparison of the analog control signal with a slope signal. The analog control signal generation circuit raises the maximum value (an internal supply voltage) of the analog control signal with a predetermined gradient during the start-up or renewed start-up of the output voltage.

### CROSS REFERENCE TO RELATED APPLICATIONS

This application is a continuation under 35 U.S. C. § 120 of PCT/JP2024/014715 filed on Apr. 11, 2024. Priority under 35 U.S. C. § 119(a) and 35 U.S. C. § 365(b) is claimed from Japanese Application No. 2023-091614 filed Jun. 2, 2023, the disclosure of which is also incorporated herein by reference.

### TECHNICAL FIELD

The present disclosure relates to power supply circuits, signal transmission devices, electronic devices, and vehicles.

### BACKGROUND ART

Conventionally, signal transmission devices that transmit a signal between a primary and a secondary circuit system while electrically isolating between them are used in a variety of applications (such as power supply devices and motor driving devices).

One example of conventional technology related to what has just been mentioned is found in Patent Document 1, identified below, by the present applicant.

### CITATION LIST

### Patent Literature

Patent Document 1: WO 2022/070944

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing the overall configuration of a signal transmission device.

FIG. 11 is a diagram showing one configuration example of an electronic device incorporating a signal transmission device.

FIG. 12 is a diagram showing a power supply circuit according to a first embodiment.

FIG. 13 is a diagram showing the soft-start operation in the first embodiment.

FIG. 14 is a diagram showing a power supply circuit according to a second embodiment.

FIG. 15 is a diagram showing the soft-start operation in the second embodiment.

FIG. 16 is a diagram showing the exterior appearance of a vehicle incorporating electronic devices.

### DESCRIPTION OF EMBODIMENTS

### Signal Transmission Device (Basic Configuration)

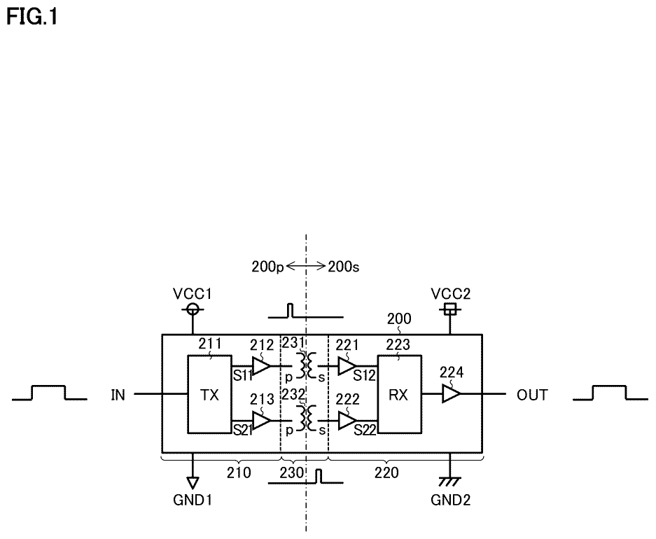

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

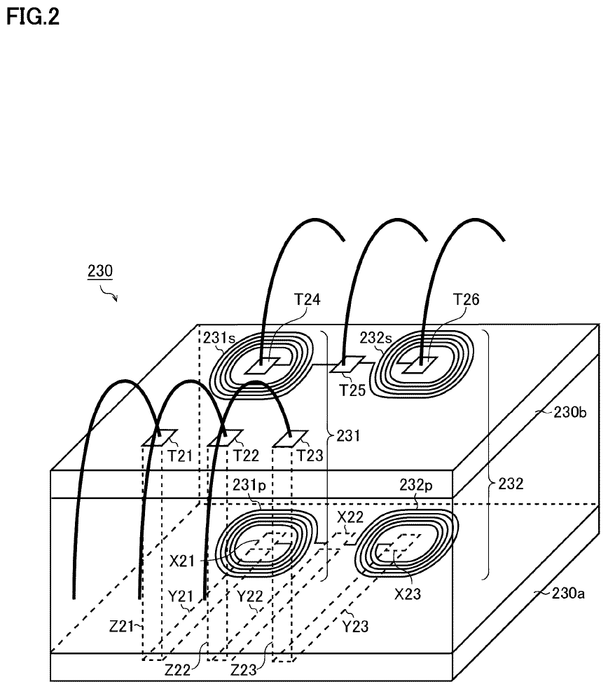

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

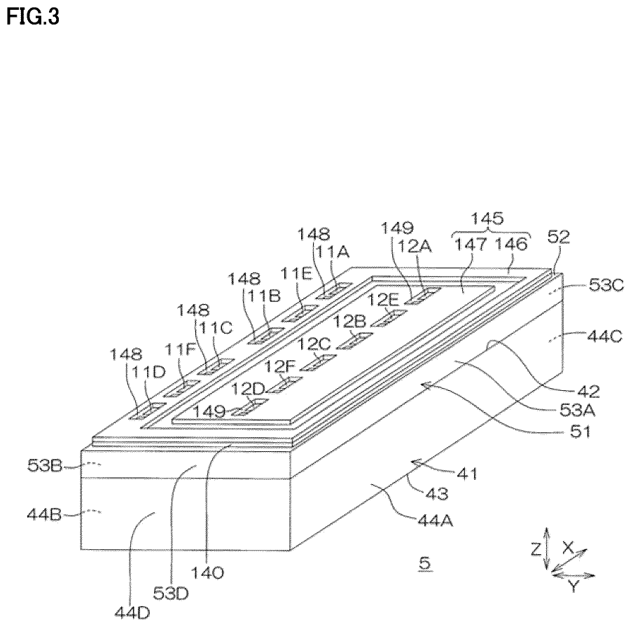

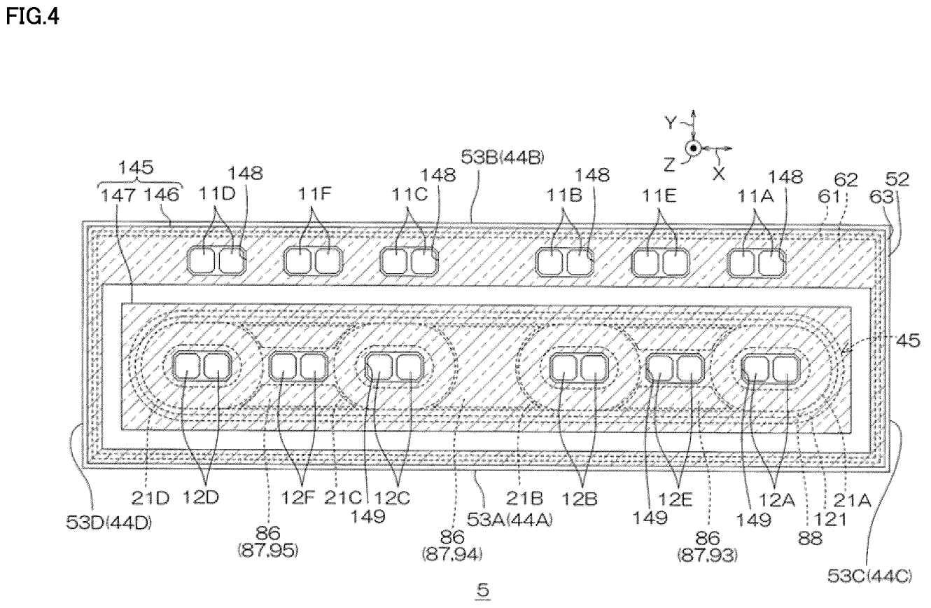

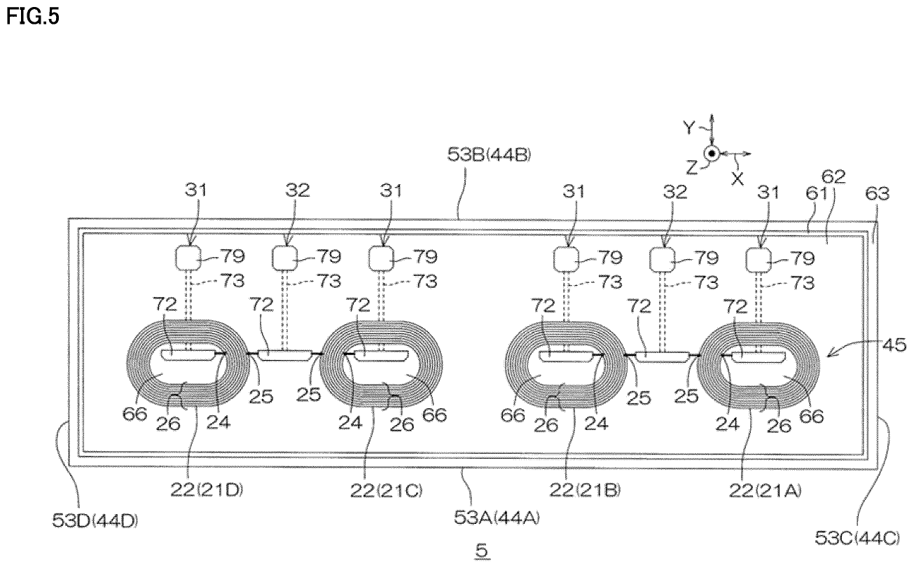

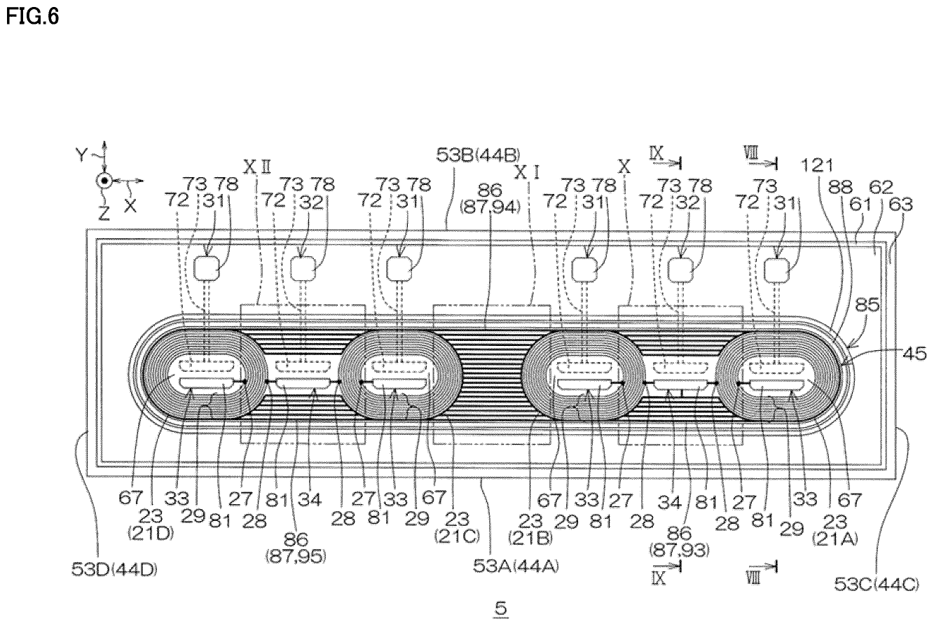

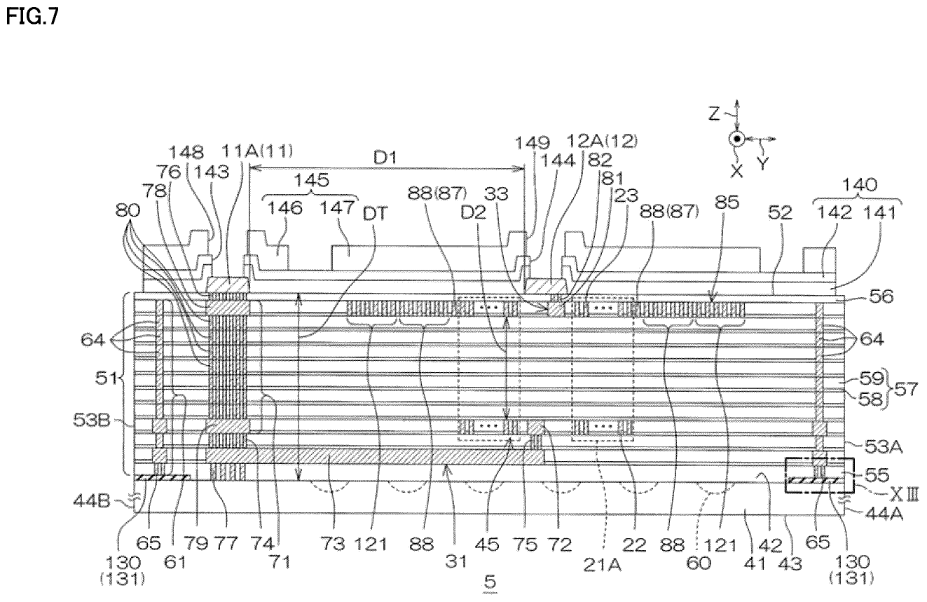

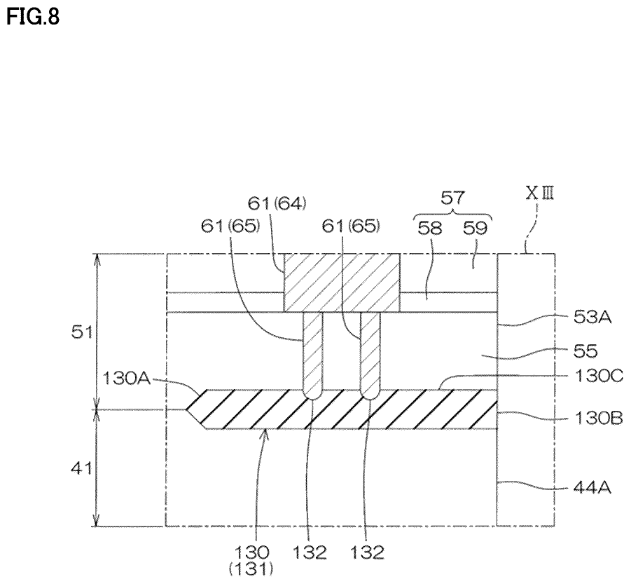

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73 and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71 and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81 and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effective electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41 and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

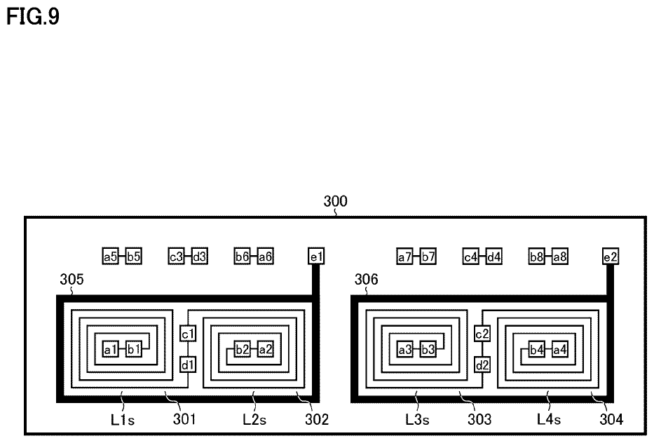

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Signal Transmission Device (Overall Configuration)

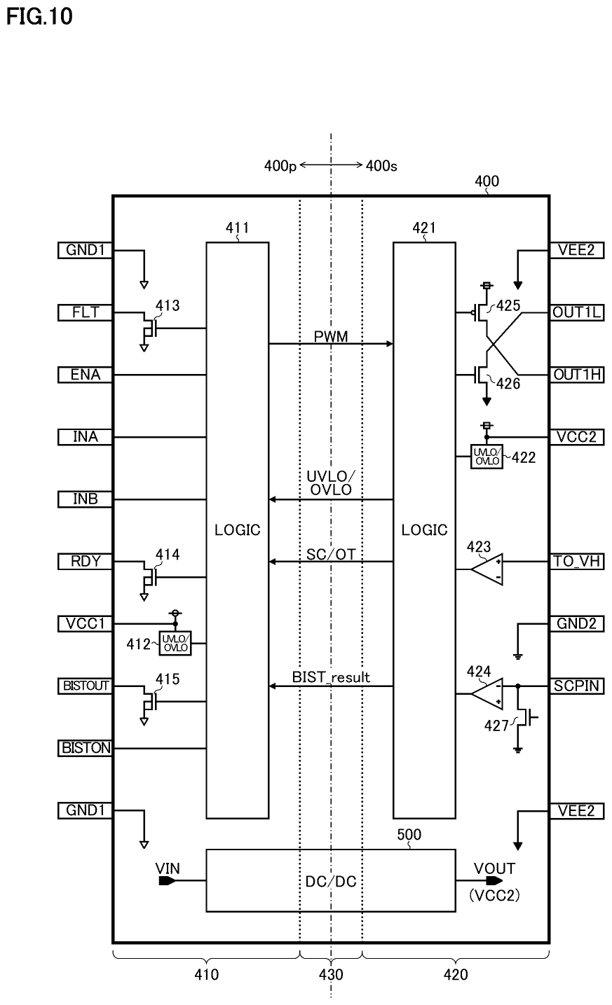

FIG. 10 is a diagram showing the overall configuration of a signal transmission device. A signal transmission device 400 according to a first embodiment is a semiconductor integrated circuit device (what is called an isolated gate driver IC) that, while electrically isolating between a primary circuit system 400p (VCC1-GND1 system) and a secondary circuit system 400s (VCC2-GND2 system), transmits a driving pulse signal PWM from the primary circuit system 400p to the secondary circuit system 400s to drive the gate of a power transistor (not shown) provided in the secondary circuit system 400s. The signal transmission device 400 can be understood to correspond to the signal transmission device 200 described previously.

The signal transmission device 400 is provided with, for electrical connection with outside the device, a plurality of external terminals (in the diagram, power terminals VCC1 and VCC2, ground terminals GND1 and GND2, a negative power terminal VEE2, input terminals INA and INB, output terminals OUT1H and OUT!L, a fault terminal FLT, a ready terminal RDY, an enable terminal ENA, an overheat/load power fault detection terminal TO_VH, a short-circuit detection terminal SCPIN, a self-diagnosis on terminal ON, and a self-diagnosis output terminal BISTOUT).

Along a first side (in the diagram, the left side) of the package of the signal transmission device 400 are arranged, from top down, the ground terminal GND1, the fault terminal FLT, the enable terminal ENA, the input terminal INA, the input terminal INB, the ready terminal RDY, the power terminal VCC1, the self-diagnosis output terminal BISTOUT, the self-diagnosis on terminal BISTON, and the ground terminal GND1.

On the other hand, along a second side of the same package (the side opposite from the above-mentioned first side, the right side in the diagram) are arranged, from top down, the negative power terminal VEE2, the output terminal OUT1L, the output terminal OUT1H, the power terminal VCC2, the overheat/load power fault detection terminal TO_VH, the ground terminal GND2, the short-circuit detection terminal SCPIN, and the negative power terminal VEE2.

As described above, the external terminals (GND1, FLT, ENA, INA, INB, RDY, VCC1, BISTOUT, and BISTON) of the primary circuit system 400p can be lined up along the first side of the package and the external terminals (VEE2, OUT1L, OUT1H, VCC2, TO_VH, GND2, and SCPIN) of the secondary circuit system 400s can be lined up along the second side of the package.

Along the first and second sides of the package, the ground terminal GND1 and the negative power terminal VEE2, respectively, can be arranged one at either end of the corresponding sides. That is, two each of the ground terminals GND1 and the negative power terminals VEE2 can be provided.

The signal transmission device 400 can be employed widely in applications in general that require signal transmission between a primary circuit system 400p and a secondary circuit system 400s with these isolated from each other (such as motor drivers and DC-DC converters that handle high voltages).

With reference still to FIG. 10, the internal configuration of the signal transmission device 400 will be described. The signal transmission device 400 of this configuration example has a controller chip 410 (corresponding to a first chip), a driver chip 420 (corresponding to a second chip), and a transformer chip 430 (corresponding to a third chip) sealed in a single package.

The controller chip 410 is a semiconductor chip having integrated in it the circuit elements of the primary circuit system 400p that operates by being supplied with a supply voltage VCC1 (e.g., 7 V at the maximum relative to GND1). Integrated in the controller chip 410 are, for example, a logic circuit 411, an UVLO (undervoltage lock-out)/OVLO (overvoltage lock-out) circuit 412, and NMOSFETs (N-channel metal-oxide-semiconductor field-effect transistors) 413 to 415.

The logic circuit 411 generates a driving pulse signal PWM for a power transistor (not shown) according to input pulse signals INA and INB. For example, if INB=H (the logic level corresponding to a disabled state), PWM=L (fixed value) and, if INB=L (the logic level corresponding to an enabled state), PWM=INA. The logic circuit 411 also has the function of monitoring various fault detection signals (such as undervoltage, overvoltage, short circuit, open circuit, overheat, and load power fault) of the signal transmission device 400 and, according to the results of the monitoring of those signals, driving the NMOSFETs 413 and 414 to determine the logic levels of a fault signal FLT and a ready signal RDY. The logic circuit 411 further has the function of, according to an enable signal ENA, operating or not operating (enabling or disabling) the entire signal transmission device 400.

The logic circuit 411 moreover has the function of, according to a self-diagnosis on signal BISTON, performing self-diagnosis (what is called BIST [built-in self tests]) on different parts of the signal transmission device 400 and, according to the results of the self-diagnosis, driving the NMOSFET 415 to determine the logic level of a self-diagnosis output signal BISTOUT. That is, the logic circuit 411 functions as part of a self-diagnosis circuit built in the signal transmission device 400.

The UVLO/OVLO circuit 412 detects an undervoltage/overvoltage, respectively, in the supply voltage VCC1 and feeds the detection result to the logic circuit 411.

According to an instruction from the logic circuit 411, the NMOSFET 413 switches between a conducting and a cut-off state the path between the fault terminal FLT and a ground terminal. For example, if overheating or a load power fault is detected in the driver chip 420, the NMOSFET 413 turns on to turn the fault terminal FLT to low level (the logic level corresponding to a fault being detected).

According to an instruction from the logic circuit 411, the NMOSFET 414 switches between a conducting and a cut-off state the path between the ready terminal RDY and the ground terminal. For example, if an undervoltage or an overvoltage is detected in either the controller chip 410 or the driver chip 420, the NMOSFET 414 turns on to turn the ready terminal RDY to low level (the logic level corresponding to a fault being detected).

According to an instruction from the logic circuit 411, the NMOSFET 415 switches between a conducting and a cut-off state the path between the self-diagnosis output terminal BISTOUT and the ground terminal. For example, if the result of self-diagnosis on the signal transmission device 400 is NG, the NMOSFET 415 turns on to turn the self-diagnosis output terminal BISTOUT to low level (the logic level corresponding to a fault being detected).

The driver chip 420 is a semiconductor chip having integrated in it the circuit elements of the secondary circuit system 400s that operates by being supplied with a supply voltage VCC2 (e.g., 30 V at the maximum relative to GND2). Integrated in the driver chip 420 are, for example, a logic circuit 421, an UVLO/OVLO circuit 422, comparators 423 and 424, a PMOSFET (P-channel MOSFET) 425, and NMOSFETs 426 and 427.

The logic circuit 421, by turning on and off the PMOSFET 425 and the NMOSFET 426 according to the driving pulse signal PWM fed in via the transformer chip 430, drives the gates of power transistors (not shown) connected to the output terminals OUT1H and OUT1L. The output terminals OUT1H and OUT1L can be short-circuited together outside the signal transmission device 400. The logic circuit 421 also has the function of transmitting various fault detection signals (such as undervoltage, overvoltage, short circuit, open circuit, overheat, and load power fault) in the driver chip 420 to the controller chip 410 via the transformer chip 430.

The logic circuit 421 further has the function of transmitting the results (BIST_results) of self-diagnosis in the driver chip 420 to the controller chip 410 via the transformer chip 430. That is, the logic circuit 421 functions as part of the self-diagnosis circuit built in the signal transmission device 400.

The UVLO/OVLO circuit 422 detects an undervoltage/overvoltage, respectively, in the supply voltage VCC2 and feeds the detection result to the logic circuit 421.

The comparator 423 monitors the terminal voltage at the overheat/load power fault detection terminal TO_VH to detect overheating of the power transistors or an overvoltage in the load power.

The comparator 424 monitors the terminal voltage at the short-circuit detection terminal SCPIN to detect a short circuit (through current across a high-side and a low-side power transistor) in the power transistors.

According to an instruction from the logic circuit 421, the PMOSFET 425 switches between a conducting and a cut-off state the path between a power terminal and the output terminal OUT1H. For example, if the driving pulse signal PWM is at high level, the PMOSFET 425 is on to keep the output terminal OUT1H (hence the output pulse signal applied to the gate of the power transistor) at high level.

According to an instruction from the logic circuit 421, the NMOSFET 426 switches between a conducting and a cut-off state the path between the output terminal OUT1L and the ground terminal. For example, if the driving pulse signal PWM is at low level, the NMOSFET 426 is on to keep the output terminal OUT1L (hence the output pulse signal applied to the gate of the power transistor) at low level.

As described above, the PMOSFET 425 and the NMOSFET 426 function as a half-bridge output stage (CMOS [complementary MOS] inverter stage) for driving gates.

According to an instruction from the logic circuit 421, the NMOSFET 427 switches between a conducting and a cut-off state the path between a ground terminal GND2 and the short-circuit detection terminal SCPIN. For example, the NMOSFET 427 is off if OUT1H=H and is on if OUT1H=L. The NMOSFET 427, by turning on and off complementarily with a power transistor (not shown), functions as a discharge switch for discharging a capacitor (not shown) externally connected between the terminals SCPIN and GND2.

The transformer chip 430 is a semiconductor chip having integrated in it a transformer for bidirectional signal transmission between the controller chip 410 and the driver chip 420 with these isolated from each other.

The signal transmission device 400 of this configuration example has, independently of the controller chip 410 and the driver chip 420, the transformer chip 430 that only has a transformer integrated in it and has these three chips sealed in a single package.

With this configuration, the controller chip 410 and the driver chip 420 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

Moreover, the controller chip 410 and the driver chip 420 can each be fabricated by a time-proven existing process. This eliminates the need for conducting reliability tests anew and contributes to a shortened development period and reduced development costs.

Moreover, use of a direct-current isolating element other than a transformer (e.g., a photocoupler) can be coped with easily by solely mounting the alternative in place of the transformer chip 430. This eliminates the need for re-developing down to the controller chip 410 and the driver chip 420 and contributes to a shortened development period and reduced development costs.

Furthermore, the signal transmission device 400 of this configuration example includes a power supply circuit 500 of an isolated type. The power supply circuit 500, while isolating between the primary circuit system 400p and the secondary circuit system 400s, generates from an input voltage VIN a desired output voltage VOUT. The output voltage VOUT can be the supply voltage VCC2 for the secondary circuit system 400s. A signal transmission device 400 like this that is provided with a power supply circuit 500 of an isolated type eliminates the need for a separate power IC for generating the supply voltage VCC2 for the secondary circuit system 400s.

### Electronic Device

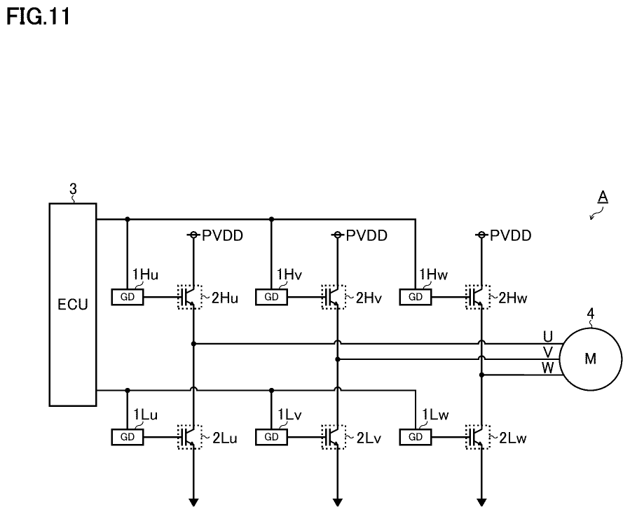

FIG. 11 is a diagram showing one configuration example of an electronic device that incorporates a signal transmission device 400. The electronic device A of this configuration example has high-side gate drivers IC1H(u/v/w), low-side gate drivers IC1L(u/v/w), high-side power transistors 2H(u/v/w), low-side power transistors 2L(u/v/w), an ECU 3, and a motor 4.

The high-side gate drivers IC1H(u/v/w) respectively drive the high-side power transistors 2H(u/v/w) by generating a high-side gate driving signal according to a high-side gate control signal fed from the ECU 3 while isolating between the ECU 3 and the high-side power transistors 2H(u/v/w).

The low-side gate drivers IC1L(u/v/w) respectively drive the low-side power transistors 2L(u/v/w) by generating a low-side gate driving signal according to a low-side gate control signal fed from the ECU 3 while isolating between the ECU 3 and the low-side power transistors 2L(u/v/w).

As each of the high-side and low-side gate drivers IC1H(u/v/w) and IC1L(u/v/w) mentioned above, the signal transmission device 400 described previously can be suitably used.

The high-side power transistors 2H(u/v/w) are respectively connected, as high-side switches constituting a three-phase (U-phase/V-phase/W-phase) half-bridge output stage, between a power-system supply terminal (an application terminal for a load supply voltage PVDD) and the input terminals of the corresponding phases of the motor 4.

The low-side power transistors 2L(u/v/w) are respectively connected, as low-side switches constituting a three-phase (U-phase/V-phase/W-phase) half-bridge output stage, between the input terminals of the corresponding phases of the motor 4 and a power-system ground terminal.

While in the diagram the high-side and low-side power transistors 2H(u/v/w) and 2L(u/v/w) are all implemented as IGBTs (insulated-gate bipolar transistors), instead of IGBTs, for example, MOSFETs (metal-oxide-semiconductor field-effect transistors) can be used.

The ECU 3 drives, via the high-side and low-side gate drivers IC1H(u/v/w) and IC1L(u/v/w), high-side and low-side power transistors 2H(u/v/w) and 2L(u/v/w) respectively and thereby controls the rotation and driving of the motor 4. The ECU 3 also has the function of monitoring the fault terminal FLT and the ready terminal RDY in each of the high-side and low-side gate drivers IC1H(u/v/w) and IC1L(u/v/w) and, according to the monitoring results, performing various kinds of safety control.

The ECU 3 further has the function of, by using the self-diagnosis on signal BISTON, making the signal transmission device 400 output self-diagnosis results and, based on the logic level of the self-diagnosis output signal BISTOUT, checking whether the various protection circuits (undervoltage protection, overvoltage protection, overheat protection, and short-circuit protection) are operating normally.

The motor 4 is a three-phase motor that is driven to rotate according to three-phase driving voltages U/V/W fed from half-bridge output stages corresponding to three phases (U phase/V phase/W phase).

### Power Supply Circuit (First Embodiment)

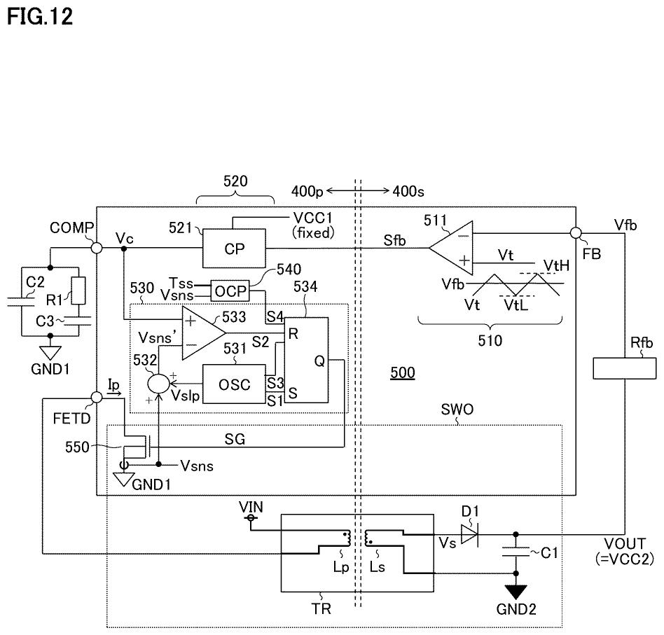

FIG. 12 is a diagram showing a power supply circuit 500 according to a first embodiment (serving as a comparative example to be compared with a second embodiment, which will be described later). The power supply circuit 500 of this embodiment is a DC-DC converter of an isolated type that generates from an input voltage VIN of a primary circuit system 400p an output voltage VOUT (e.g., supply voltage VCC2) of a secondary circuit system 400s by driving a switching output stage SWO.

For example, the power supply circuit 500 includes a pulse feedback signal generation circuit 510, an analog control signal generation circuit 520, a switching driving control circuit 530, an overcurrent protection circuit 540, an output transistor 550, and various discrete components (a transformer TR, a diode D1, capacitors C1 to C3, a resistor R1, and a feedback resistor circuit Rfb).

The transformer TR has a primary coil Lp (with a number of turns Np) and a secondary coil Ls (with a number of turns Ns) that electrically isolate between the primary circuit system 400p and the secondary circuit system 400s but that are magnetically coupled together.

The first terminal (winding start terminal) of the primary coil Lp is connected to an application terminal for the input voltage VIN. The second terminal (winding end terminal) of the primary coil Lp is connected via a FETD pin of the signal transmission device 400 to the drain of an output transistor 550 (in the diagram, an NMOSFET). The gate of the output transistor 550 is connected to an application terminal for a gate driving signal SG. The source of the output transistor 550 is connected to the ground terminal of the primary circuit system 400p.

So connected, the output transistor 550 functions as a switching element for turning on and off a primary current Ip according to the gate driving signal SG. In a case where the output transistor 550 is implemented with an NMOSFET, the output transistor 550 is on if the gate driving signal SG is at high level and is off if the gate driving signal SG is at low level. The output transistor 550 can be externally connected to the signal transmission device 400. In that case, instead of the FETD pin, an FETG pin (a terminal connected to the gate of the output transistor 550) can be provided.

The first terminal (winding end terminal) of the secondary coil Ls and the anode of the diode D1 are both connected to an application terminal for a secondary voltage Vs. The cathode of the diode D1 and the first terminal of the capacitor C1 are both connected to an application terminal for the output voltage VOUT (=supply voltage VCC2). The second terminal (winding start terminal) of the secondary coil Ls and the second terminal of the capacitor C1 are both connected to the ground terminal of the secondary circuit system 400s.

The output transistor 550, the transformer TR, the diode D1, and the capacitor C1 constitute a switching output stage SWO of a flyback type that generates the output voltage VOUT (=supply voltage VCC2) of the secondary circuit system 400s from the input voltage VIN of the primary circuit system 400p while isolating between the primary circuit system 400p and the secondary circuit system 400s.

The basic operation of the switching output stage SWO will be described. The switching output stage SWO drives the primary current Ip passing through the primary coil Lp of the transformer TR so as to generate the output voltage VOUT from the secondary voltage Vs induced in the secondary coil Ls of the transformer TR.

For example, in the on period of the output transistor 550, the primary current Ip passes from the application terminal for the input voltage VIN via the primary coil Lp and the output transistor 550. Accordingly, energy is stored in the primary coil Lp. After that, when the output transistor 550 is turned off, in the secondary coil Ls, which is magnetically coupled with the primary coil Lp, the secondary voltage Vs is induced. The secondary voltage Vs is rectified and smoothed through the diode D1 and the capacitor C1. Through this rectifying and smoothing operation, from the secondary voltage Vs, the output voltage VOUT (=supply voltage VCC2) is generated. After that, the output transistor 550 continues to be turned on and off so as to repeat switching output operation in a similar manner as described above.

The numbers of turns Np and Ns of the transformer TR can be adjusted as desired so as to yield the desired output voltage VOUT (=VIN×(Ns/Np)×(Ton/Toff), where Ton and Toff are the on and off periods, respectively, of the output transistor 550). For example, the greater the number of turns Np, or the smaller the number of turns Ns, the lower the output voltage VOUT (=supply voltage VCC2); the other way around, the smaller the number of turns Np, or the greater the number of turns Ns, the higher the output voltage VOUT (=supply voltage VCC2).

The feedback resistor circuit Rfb generates a feedback voltage Vfb corresponding to the output voltage VOUT. The feedback voltage Vfb can be, for example, a division voltage of the output voltage VOUT. That is, the feedback resistor circuit Rfb can be a resistor voltage division circuit. The feedback voltage Vfb can be applied to an FB pin of the signal transmission device 400.

The pulse feedback signal generation circuit 510 generates a pulse feedback signal Sfb that carries pulse information (e.g., the duty) corresponding to the output voltage VOUT (=supply voltage VCC2) and feeds the pulse feedback signal Sfb from the secondary circuit system 400s to the primary circuit system 400p. In terms of what is shown in the diagram, the pulse feedback signal generation circuit 510 includes a comparator 511. The pulse feedback signal generation circuit 510 can be provided in the secondary circuit system 400s (in particular, the driver chip 420).

The comparator 511 generates the pulse feedback signal Sfb by comparing the feedback voltage Vfb, which is fed to the inverting input terminal (−) of the comparator 511, with a triangular wave voltage Vt, which is fed to the non-inverting input terminal (+) of the comparator 511. The triangular wave voltage Vt is a voltage signal with a triangular waveform (or sawtooth waveform) that repeats rising and falling at a predetermined oscillation frequency (e.g., 200 kHz). The high level VtH of the triangular wave voltage Vt can be, for example, 2.5 V; the low level VtL of the triangular wave voltage Vt can be, for example 0.5 V. These high and low levels VtH and VtL can each be adjusted by trimming.

The pulse feedback signal Sfb is at high level if the triangular wave voltage Vt is higher than the feedback voltage Vfb; the pulse feedback signal Sfb is at low level if the triangular wave voltage Vt is lower than the feedback voltage Vfb. That is, the duty (i.e., the proportion of the on period in the pulse period) decreases as the feedback voltage Vfb increases and increases as the feedback voltage Vfb decreases. For example, if Vfb=(VH+VL)/2=1.5V, the duty of the pulse feedback signal Sfb is 50%

The analog control signal generation circuit 520 operates by being supplied with the supply voltage VCC1 (with a fixed value) and generates an analog control voltage Vc corresponding to the pulse feedback signal Sfb. The analog control signal generation circuit 520 can be provided in the primary circuit system 400p (in particular, the controller chip 410).

In terms of what is shown in the diagram, the analog control signal generation circuit 520 includes a charge pump 521. The charge pump 521 varies an analog control signal Vc according to the duty of the pulse feedback signal Sfb.

For example, the charge pump 521 can generate the analog control signal Vc by increasing and decreasing a positive or negative current (e.g., ±100 μA) passing through a COMP pin according to the duty of the pulse feedback signal Sfb. The COMP pin can have externally connected to it a phase compensation circuit that includes the capacitor C2 and the resistor R1.

In that case, the analog control signal Vc is a voltage signal that corresponds to the duty of the pulse feedback signal Sfb. For example, the analog control signal Vc rises when the pulse feedback signal Sfb is at high level and falls when the pulse feedback signal Sfb is at low level. The positive-negative ratio of the current generated by the charge pump 521 can be left adjustable by trimming.

The switching driving control circuit 530 controls the duty of the gate driving signal SG according to the analog control signal Vc such that the output voltage VOUT (=supply voltage VCC2) is equal to a target value. That is, the switching driving control circuit 530 controls the switching output stage SWO such that this drives the primary current Ip according to the analog control signal Vc. The switching driving control circuit 530 can be provided in the primary circuit system 400p (in particular, the controller chip 410).

In terms of what is shown in the diagram, the switching driving control circuit 530 includes an oscillator 531, an adder 532, a comparator 533, and an RS flip-flop 534.

The oscillator 531 generates a set signal S1, a slope signal Vslp, and a maximum duty setting signal S3. The set signal S1 is pulse-driven at a predetermined switching frequency fsw (e.g., 100 kHz). The slope signal Vslp starts rising in synchronization with the set signal S1. The maximum duty setting signal S3 is pulse-driven when, after a pulse is generated in the set signal S1, a predetermined maximum on period Ton_max elapses.

The adder 532 generates an added sense signal Vsns'by adding up the slope signal Vslp and a sense signal Vsns. The sense signal Vsns can be a voltage signal corresponding to the primary current Ip.

The comparator 533 generates a reset signal S2 by comparing the added sense signal Vsns′, which is fed to the inverting input terminal (−) of the comparator 533, with the analog control signal Vc, which is fed to the non-inverting input terminal (+) of the comparator 533. The reset signal S2 is at low level if the added sense signal Vsns'is higher than the analog control signal Vc; the reset signal S2 is at high level if the added sense signal Vsns′ is lower than the analog control signal Vc.

The RS flip-flop 534 determines the logic level of the gate driving signal SG output from its output terminal (Q) according to the set signal S1, which is fed to the set terminal (S) of the RS flip-flop 534, and three control signals (the reset signal S2, the maximum duty setting signal S3, and an overcurrent protection signal S4) that are fed to the reset terminals (R) of the RS flip-flop 534 so that this takes the OR of those signals.

For example, the RS flip-flop 534 sets the gate driving signal SG to high level (the logic level to turn on the output transistor 550) in response to the set signal S1 rising to high-level. On the other hand, the RS flip-flop 534 resets the gate driving signal SG to low level (the logic level to turn off the output transistor 550) in response to either the reset signal S2 or the maximum duty setting signal S3 rising to high level.

As described above, the switching driving control circuit 530 drives the switching output stage SWO according to the result of comparison of the analog control signal Vc with the added sense signal Vsns′ (hence the slope signal Vslp).

The overcurrent protection circuit 540 generates the overcurrent protection signal S4 so as to limit the primary current Ip passing through the primary coil Lp of the transformer TR via the output transistor 550 to below or equal to an overcurrent detection value Iocp. The overcurrent protection signal S4 is at high level (the logic level corresponding to an overcurrent being detected) if the sense signal Vsns is higher than a threshold voltage Vocp. On the other hand, the overcurrent protection signal S4 is at low level (the logic level corresponding to no overcurrent being detected) if the sense signal Vsns is lower than the threshold voltage Vocp. The overcurrent protection circuit 540 can be provided in the primary circuit system 400p (in particular, the controller chip 410).

For example, if the overcurrent protection signal S4 is at high level (the logic level corresponding to an overcurrent being detected), irrespective of the logic levels of the reset signal S2 and the maximum duty setting signal S3, the gate driving signal SG is fixed at low level. As a result, the output transistor M1 is forcibly kept in on state.

The overcurrent protection circuit 540 is provided with a function, what is called a soft-start function, of gently raising the output voltage VOUT by raising the threshold voltage Vocp (hence the overcurrent detection value Iocp) stepwise over a soft-start period Tss.

### Soft-Start Operation (First Embodiment)

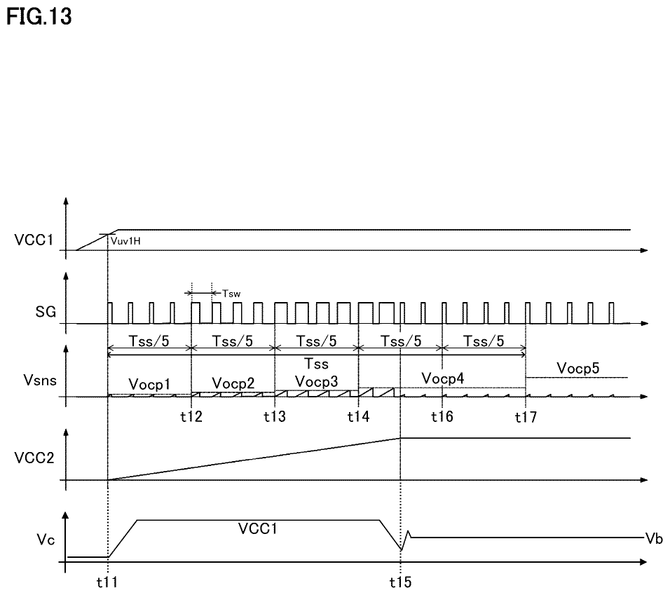

FIG. 13 is a diagram showing the soft-start operation in the first embodiment. The diagram depicts, from top down, the supply voltage VCC1, the gate driving signal SG, the sense signal Vsns, the supply voltage VCC2 (=output voltage VOUT), and the analog control signal Vc.

When at time t11 the supply voltage VCC1 becomes higher than an undervoltage cancel threshold voltage Vuv1H, switching control for the gate driving signal SG is started. As a result, the supply voltage VCC2 (=output voltage VOUT) starts to rise.

Moreover, at time t11, the soft-start period Tss (e.g., 12.5 ms) starts to be counted. In terms of what is shown in the diagram, the period between times t11 and t17 corresponds to the soft-start period Tss.

Here, the overcurrent protection circuit 540 raises the threshold voltage Vocp (hence the overcurrent detection value Iocp) stepwise over the soft-start period Tss.

For example, between times t11 and t12, the threshold voltage Vocp is set to a first, the lowest, set value Vocp1. The first set value Vocp1 can be set to 40 mV. The period between times t11 and t12 can be set to one-fifth of the soft-start period Tss.

Between times t12 and t13, the threshold voltage Vocp is set to a second set value Vocp2 one step higher than the first set value Vocp1. The second set value Vocp2 can be set to 60 mV, The period between times t12 and t13 can be set to one-fifth of the soft-start period Tss.

Between times t13 and t14, the threshold voltage Vocp is set to a third set value Vocp3 one step higher than the second set value Vocp2. The third set value Vocp3 can be set to 80 mV, The period between times t13 and t14 can be set to one-fifth of the soft-start period Tss.

Between times t14 and t16 and also between times t16 and t17, the threshold voltage Vocp is set to a fourth set value Vocp4 one step higher than the third set value Vocp3. The fourth set value Vocp4 can be set to 100 mV, The period between times t14 and t16 and the period between times t16 and t17 can each be set to one-fifth of the soft-start period Tss.

After time t17 when the counting of the soft-start period Tss is complete, the threshold voltage Vocp is set to a fifth set value Vocp5 one step higher than the fourth set value Vocp4. The fifth set value Vocp5 can be set to 200 mV. The fifth set value Vocp5 is set appropriately with consideration given to the normal range of the primary current Ip passing when the power supply circuit 500 is in a steady state.

Moreover, the overcurrent protection circuit 540 performs overcurrent protection operation of a hiccup type as follows: if the sense signal Vsns becomes higher than the threshold voltage Vocp while the supply voltage VCC2 (=output voltage VOUT) is starting up, that is, before the lapse of the soft-start period Tss, the overcurrent protection circuit 540 forcibly keeps the primary current Ip off until the next on timing in the switching period Tsw of the primary current Ip.

With the overcurrent protection operation described above, switching control for the primary current Ip is performed such that the primary current Ip increases gradually. As a result, the supply voltage VCC2 (=output voltage VOUT) rises gently over the period between times t11 and t15.

As described above, with the power supply circuit 500 according to this embodiment, it is possible, without directly monitoring with the controller chip 410 the supply voltage VCC2 (output voltage VOUT) generated by the driver chip 420, to achieve soft-start operation for the supply voltage VCC2 (output voltage VOUT).

The soft-start operation described above can be performed not only during the start-up of the supply voltage VCC2 (=output voltage VOUT) but also during a renewed start-up of the supply voltage VCC2 (=output voltage VOUT) after cancellation of fault protection operation.

Inconveniently, with the soft-start operation by the overcurrent protection circuit 540, while the supply voltage VCC2 (=output voltage VOUT) is lower than the target value, more precisely, while the duty of the pulse feedback signal Sfb is higher than the 50%, the analog control signal Vc keeps rising. Thus, the analog control signal Vc may be held at the maximum value (=supply voltage VCC1).

In that situation, when the analog control signal Vc falls from the maximum value to a bias point Vb, ringing may occur (see time t15). Ringing of the analog control signal Vc is one of the factors that destabilize output feedback control. To cope with this problem, a second embodiment will be presented below.

### Power Supply Circuit (Second Embodiment)

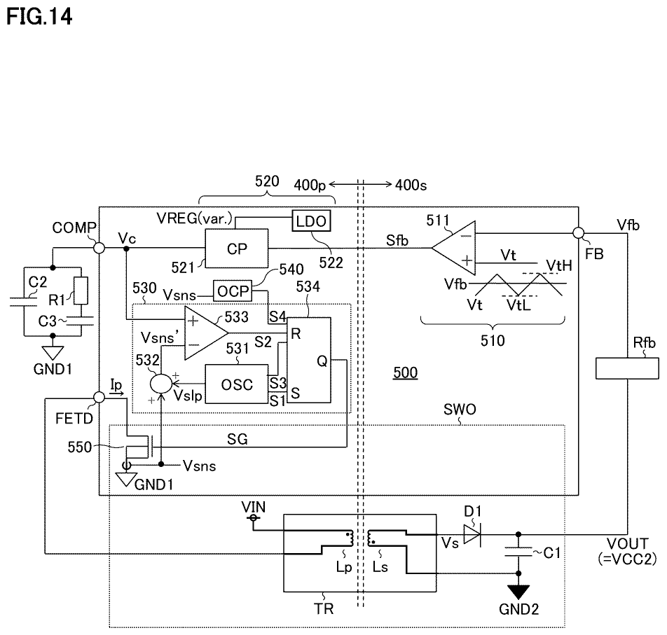

FIG. 14 is a diagram showing a power supply circuit 500 according to a second embodiment. The power supply circuit 500 of this embodiment is based on the first embodiment (FIG. 12) described previously and is provided with, instead of the soft-start function by the overcurrent protection circuit 540, a soft-start function by the analog control signal generation circuit 520. In terms of what is shown in the diagram, the analog control signal generation circuit includes, instead of the charge pump 521 mentioned previously, an internal power supply circuit 522.

The internal power supply circuit 522 generates an internal supply voltage VREG and feeds it to the charge pump 521. The internal supply voltage VREG can be a variable voltage that, during the start-up or renewed start-up of the output voltage VOUT (=supply voltage VCC2), starts to rise with a predetermined gradient from a zero value (0 V) up to a set value higher than the bias point Vb of the analog control signal Vc. The internal power supply circuit 522 can include, for example, an LDO (low-dropout) regulator.

The charge pump 521 operates by being supplied with the internal supply voltage VREG. Accordingly, the maximum value of the analog control signal Vc is limited by the internal supply voltage VREG.

### Soft-Start Operation (Second Embodiment)

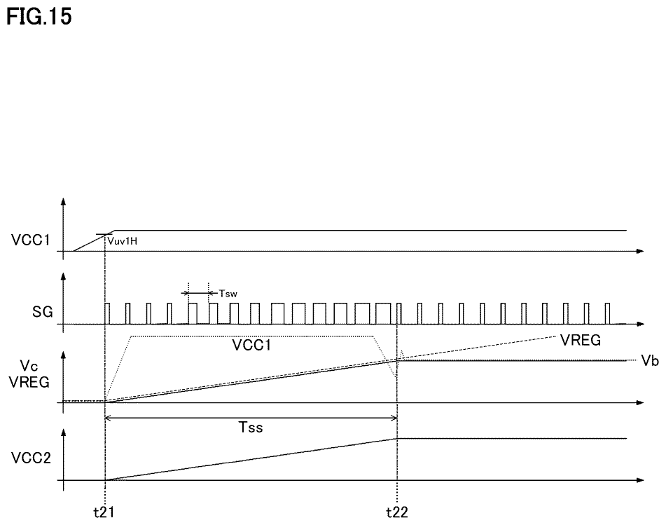

FIG. 15 is a diagram showing the soft-start operation in the second embodiment. The diagram depicts, from top down, the supply voltage VCC1, the gate driving signal SG, the analog control signal Vc (solid line) and the internal supply voltage VREG (long-dash broken line), and the supply voltage VCC2 (=output voltage VOUT). For the analog control signal Vc, in addition to its behavior in the second embodiment (solid line) also its behavior in the first embodiment (short-dash broken line) is depicted for comparison.

When at time t21 the supply voltage VCC1 becomes higher than the undervoltage cancel threshold voltage Vuv1H, switching control for the gate driving signal SG is started. As a result, the supply voltage VCC2 (=output voltage VOUT) starts to rise.

Here, starting at time t21, the internal supply voltage VREG rises with a predetermined gradient from a zero value (0 V) up to a set value higher than the bias point Vb of the analog control signal Vc. Accordingly, as the internal supply voltage VREG rises, also the maximum value of the analog control signal Vc is raised gradually. This keeps the duty of the output transistor 550 from becoming excessively high and thus the supply voltage VCC2 (=output voltage VOUT) rises gently.

After that, when at time t22 the supply voltage VCC2 (=output voltage VOUT) reaches the target value, the analog control signal Vc settles at the bias point Vb. That is, the supply voltage VCC2 (=output voltage VOUT) rises gently up to the target value over a predetermined soft-start period Tss (i.e., between times t21 and t22) without exhibiting an overshoot.

In this way, the power supply circuit 500 according to this embodiment, unlike that of the first embodiment described previously (FIG. 12), suppresses ringing. It is thus possible to enhance the stability of output feedback control.

### Application to Vehicles

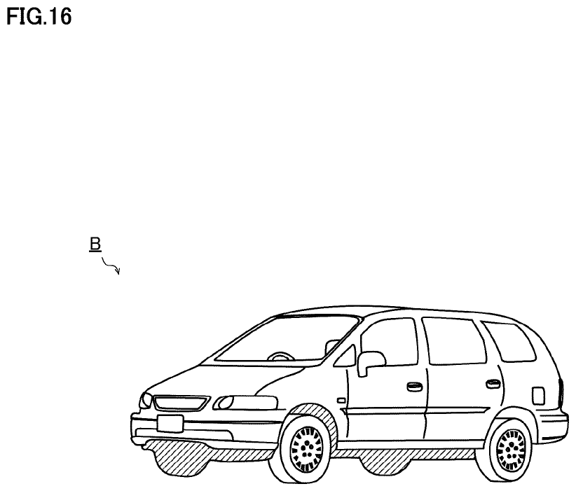

FIG. 16 is a diagram showing an exterior appearance of a vehicle. The vehicle B of this configuration example incorporates various electronic devices that operate by being supplied with electric power from a battery.

The vehicle B can be an engine vehicle, or an electric vehicle (xEV such as BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle].

The signal transmission device 200 or 400 described previously can be built in any of the electronic devices incorporated in the vehicle B.

### Overview

According to the present disclosure herein, it is possible to implement a soft-start function in a power supply circuit of an isolated type. To follow is an overview of the various embodiments disclosed herein.

For example, according to one aspect of what is disclosed herein, a power supply circuit is configured to generate from the input voltage of a primary circuit system the output voltage of a secondary circuit system by driving a switching output stage. The power supply circuit includes: a pulse feedback signal generation circuit configured to generate a pulse feedback signal corresponding to the output voltage; an analog control signal generation circuit configured to generate an analog control signal corresponding to the pulse feedback signal; and a switching driving control circuit configured to drive the switching output stage according to the result of comparison of the analog control signal with a slope signal. The analog control signal generation circuit raises the maximum value of the analog control signal with a predetermined gradient during the start-up or renewed start-up of the output voltage. (A first configuration.) In the power supply circuit of the first configuration described above, the analog control signal generation circuit can include a charge pump configured to vary the analog control signal according to the duty of the pulse feedback signal. (A second configuration.) In the power supply circuit of the second configuration described above, the analog control signal generation circuit can further include an internal power supply circuit configured to generate an inner supply voltage that starts to rise from a zero value during the start-up or renewed start-up of the output voltage. The charge pump can operate by being supplied with the inner supply voltage. (A third configuration.)

In the power supply circuit of the first to third configurations described above, the switching driving control circuit can include: an oscillator configured to generate a set signal at a predetermined switching frequency; a comparator configured to generate a reset signal by comparing the analog control signal with the slope signal; and a flip-flop configured to generate a driving signal for the switching output stage according to the set signal and the reset signal. (A fourth configuration.)

In the power supply circuit of the first to fourth configurations described above, the switching output stage can drive a primary current passing in the primary coil of a transformer to generate the output voltage from a secondary voltage induced in the secondary coil of the transformer. (A fifth configuration.)

The power supply circuit of the fifth configuration described above can further include an overcurrent protection circuit configured to limit the primary current to below or equal to a predetermined overcurrent detection value. (A sixth configuration.)

For example, according to another aspect of what is disclosed herein, a signal transmission device includes: the power supply circuit of any of the first to sixth configurations described above; and a signal transmission circuit configured to transmit a pulse drive signal from the primary circuit system to the secondary circuit system while isolating between the primary and secondary circuit systems. (A seventh configuration.)

In the signal transmission device of the seventh configuration described above, a first chip having the circuit elements of the primary circuit system integrated in it, a second chip having the circuit elements of the secondary circuit system integrated in it, and a third chip having integrated therein an insulating element for isolating between the primary and secondary circuit systems can be sealed in a single package. (A eighth configuration.)

For example, according to another aspect of what is disclosed herein, an electronic device includes: a power transistor; and a gate driver IC configured to drive the gate of the power transistor. Here, the gate driver IC is the signal transmission device of the seventh or eighth configurations described above. (A nineth configuration.)

For example, according to another aspect of what is disclosed herein, a vehicle includes the electronic device of the ninth configuration described above (A tenth configuration).

### Further Modifications

The various technical features disclosed herein may be implemented in any manners other than as in the embodiments described above and allow for many modifications without departure from the spirit of their technical ingenuity. That is, the embodiments described above should be understood to be in every aspect illustrative and not restrictive, and the technical scope of the present invention is defined not by the description of the embodiments given above but by the appended claims and encompasses any modifications within a scope equivalent in significance to what is claimed.

1. A power supply circuit configured to generate from an input voltage of a primary circuit system an output voltage of a secondary circuit system by driving a switching output stage, the power supply circuit comprising:
a pulse feedback signal generation circuit configured to generate a pulse feedback signal corresponding to the output voltage;
an analog control signal generation circuit configured to generate an analog control signal corresponding to the pulse feedback signal; and
a switching driving control circuit configured to drive the switching output stage according to a result of comparison of the analog control signal with a slope signal,
wherein
the analog control signal generation circuit raises a maximum value of the analog control signal with a predetermined gradient during start-up or renewed start-up of the output voltage.

2. The power supply circuit according to claim 1, wherein
the analog control signal generation circuit includes a charge pump configured to vary the analog control signal according to a duty of the pulse feedback signal.

3. The power supply circuit according to claim 2, wherein
the analog control signal generation circuit further includes an internal power supply circuit configured to generate an inner supply voltage that starts to rise from a zero value during the start-up or renewed start-up of the output voltage, and
the charge pump operates by being supplied with the inner supply voltage.

4. The power supply circuit according to claim 1, wherein
the switching driving control circuit includes:
an oscillator configured to generate a set signal at a predetermined switching frequency;
a comparator configured to generate a reset signal by comparing the analog control signal with the slope signal; and
a flip-flop configured to generate a driving signal for the switching output stage according to the set signal and the reset signal.

5. The power supply circuit according to claim 1, wherein
the switching output stage drives a primary current passing in a primary coil of a transformer to generate the output voltage from a secondary voltage induced in a secondary coil of the transformer.

6. The power supply circuit according to claim 5, further comprising:
an overcurrent protection circuit configured to limit the primary current to below or equal to a predetermined overcurrent detection value.

7. A signal transmission device comprising:
the power supply circuit according to claim 1; and
a signal transmission circuit configured to transmit a pulse drive signal from the primary circuit system to the secondary circuit system while isolating between the primary and secondary circuit systems.

8. The signal transmission device according to claim 7, wherein
a first chip having circuit elements of the primary circuit system integrated therein,
a second chip having circuit elements of the secondary circuit system integrated therein, and
a third chip having integrated therein an insulating element for isolating between the primary and secondary circuit systems are sealed in a single package.

9. An electronic device comprising:
a power transistor; and
a gate driver IC configured to drive a gate of the power transistor,
wherein
the gate driver IC is the signal transmission device according to claim 7.

10. A vehicle comprising the electronic device according to claim 9.
